(19) United States
(12) Patent Application Publication
(10) Pub. No.: US 2022/0364218 A1
(43) Pub. Date: Nov. 17, 2022

(54) ALIGNMENT DEVICE

(71) Applicant: V TECHNOLOGY CO., LTD., Kanagawa (JP)

(72) Inventors: Tadashi WAKABAYASHI, Kanagawa (JP); Masami TAKIMOTO, Kanagawa (JP); Masashi NOMOTO, Kanagawa (JP)

(73) Assignee: V TECHNOLOGY CO., LTD., Kanagawa (JP)

(21) Appl. No.: 17/772,893

(22) PCT Filed: Sep. 29, 2020
(86) PCT No.: PCT/JP2020/036937

§ 371 Date: Apr. 28, 2022

(30) Foreign Application Priority Data
Nov. 8, 2019 (JP) 2019-203185

(51) Int. Cl. C23C 14/04; H01L 21/68; G06T 7/00; G06T 7/73; C23C 16/04; C23C 14/54; C23C 16/52

(52) U.S. Cl. CPC C23C 14/042; H01L 21/682; G06T 7/0004; G06T 7/73; C23C 16/042; C23C 14/54; C23C 16/52; G06T 2207/30204; G06T 2207/30148

(57) ABSTRACT

Following a determination that the distance along the Z-direction between the substrate and the mask is greater than the distance along the Z-direction to the nearest end of depth of field (DOF) for a camera from the near side of the mask, a control unit reduces the distance between the X-Y position of a substrate-mark and the X-Y position of the associated mask-mark, with a high-speed relative approach along the Z-direction between the substrate and the mask. Following a determination that the distance along the Z-direction between the substrate and the mask is equal to or less than the distance along the Z-direction to the nearest end of depth of field (DOF) from the near side of the mask, the control unit reduces the distance between the X-Y position of the substrate-mark and the X-Y position of the associated mask-mark, with a reduced-speed relative approach along the Z-direction.

### TECHNICAL FIELD

The present invention relates to systems for alignment used in the semiconductor manufacturing industry.

### BACKGROUND

There are known alignment systems, which can align a substrate to the associated mask, incorporated in film forming apparatuses for depositing film forming material on the substrate at regions uncovered by the mask.

A known alignment system described in Patent Document 1 uses a low-magnification camera and a high-magnification camera. The low-magnification camera takes the image of coarse marks on a mask for use in measurement of the positions of the coarse marks, while the high-magnification camera is moved to find fine marks on the mask within its field of view. The low-magnification camera takes the image of the coarse marks on the substrate together with the coarse marks on the mask to align the substrate and mask to one another. The high-magnification camera takes the image of the fine marks on the substrate together with the fine marks on the mask to precisely align the substrate and mask to one another.

### PRIOR ART

### Patent Literature

Patent Literature 1: JP2015-67845A

### SUMMARY OF THE INVENTION

### Problem to be Solved by the Invention

The known alignment system described in Patent Document 1, in which the rough and precise alignment are followed by contact-making of the substrate and mask, requires a long time from the commencement of the alignment to the contact of the substrate and mask with each other.

Therefore, it is an object of the present invention to provide an alignment device intended to reduce the time required from the commencement of the alignment to the contact of the substrate and mask with each other.

### Means for Solving the Problem

There is provided an alignment device, including:

an imaging device adjusted to focus on the near side of a mask for taking an image including a substrate-mark on a substrate and the associated mask-mark on the mask; and

a control unit configured to calculate the distance between the X-Y position of the substrate-mark and the X-Y position of the associated mask-mark using the data obtained from the image taken by the imaging device,

the control unit executing a first alignment process following the determination that the distance along the Z-direction between the substrate and the mask is greater than the distance along the Z-direction to the nearest end of depth of field (DOF) for the imaging device from the near side of the mask,

the first alignment process including a movement of at least one of the substrate and the mask in a direction of reducing the calculated distance, which movement takes place concurrently with a first relative approach taking place at a first predetermined speed along the Z-direction between the substrate and the mask, and

the control unit executing a second alignment process following the determination that the distance along the Z-direction between the substrate and the mask is equal to or less than the distance along the Z-direction to the nearest end of depth of field (DOF) for the imaging device from the near side of the mask,

the second alignment process including the movement of at least one of the substrate and the mask in the direction of reducing the calculated distance, which movement takes place concurrently with a second relative approach taking place at a second predetermined speed along the Z-direction between the substrate and the mask, the second predetermined speed being slower than the first predetermined speed.

As described, both the calculation of the distance between the X-Y position of a substrate-mark and the X-Y position of the associated mask-mark and the movement of at least one of the substrate and the mark in a direction of reducing the calculated distance take place concurrently with a relative approach between the substrate and the mask. Thus, this configuration may reduce the time required from the commencement of the alignment to the contact of the substrate and mask with each other.

In the alignment device,

following determination that the distance along the Z-direction between the substrate and the mask is greater than the distance along the Z-direction to the nearest end of depth of field (DOF) for the imaging device from the near side of the mask, the control unit instructs one of motions of a first series, each motion having a first predetermined duration, to provide a segment of the first relative approach in each cycle of repletion of the execution of the first alignment process, and

following determination that the distance along the Z-direction between the substrate and the mask is less than or equal to the distance along the Z-direction to the nearest end of depth of field (DOF) for the imaging device from the near side of the mask, the control unit instructs one of motions of a second series, each motion having a second predetermined duration, which is less than the first predetermined duration, to provide a segment of the second relative approach in each cycle of repetition of the execution of the second alignment process.

Each motion with a predetermined relative long duration is instructed to provide a segment of the first relative approach in each cycle of repetition of the first alignment process, and each with a predetermined relative short duration is instructed to provide a segment of the second relative approach in each cycle of repetition of the second alignment process. Thus, this configuration may reduce the time required from the commencement of the alignment to the contact of the substrate and mask with each other.

In accordance with another aspect, there is provided an alignment device, including:

an imaging device adjusted to focus on the near side of a mask for taking an image including a substrate-mark on a substrate and the associated mask mark on the mask; and

a control unit configured to calculate the distance between the X-Y position of the substrate-mark and the X-Y position of the associated mask-mark using the data obtained from the image taken by the imaging device,

the control unit controls a first relative approach along the Z-direction between the substrate and the mask until the distance along the Z-direction between the substrate and the mask is equal to the distance along the Z-direction to the nearest end of depth of field (DOF) for the imaging device from the near side of the mask, and subsequently executes an alignment process including a movement of at least one of the substrate and the mask in a direction of reducing the calculated distance, which movement takes place concurrently with a second relative approach taking place at a predetermined speed along the Z-direction between the substrate and the mask.

Immediately after reaching the nearest end of depth of field (DOF) for the imaging device, the control unit commences the execution of an alignment process including a movement of at least one of the substrate and the mask in a direction of reducing the calculated distance, which movement takes place concurrently with a second relative approach taking place at a predetermined speed along the Z-direction between the substrate and the mask. Thus, this configuration may reduce the time required from the commencement of the alignment to the contact of the substrate and mask with each other.

In the alignment device, the control unit executes the position correction for the movement of at least one of the substrate and the mask in a direction of reducing the calculated distance, using a correction value dependent on the distance along the Z-direction between the substrate and the mask.

The position correction for the movement of at least one of the substrate and the mask is executed, using a correction value dependent on the distance along the Z-direction between the substrate and the mask. Thus, this configuration may provide precise alignment of the substrate and the mask.

In accordance with still another aspect, there is provided a method for alignment and contact-making of a substrate with a mask, using an imaging device adjusted to focus on the near side of a mask for taking an image including a substrate-mark on a substrate and the associated mask-mark on the mask, and a control unit configured to calculate the distance between the X-Y position of the substrate-mark and the X-Y position of the associated mask-mark using the data obtained from the image taken by the imaging device, the method comprising:

executing a first alignment process following determination that the distance along the Z-direction between the substrate and the mask is greater than the distance along the Z-direction to the nearest end of depth of field (DOF) for the imaging device from the near side of the mask,

the first alignment process including a movement of at least one of the substrate and the mask in a direction of reducing the calculated distance, which movement takes place concurrently with a relative approach taking place at a predetermined speed along the Z-direction between the substrate and the mask, and

executing a second alignment process following determination that the distance along the Z-direction between the substrate and the mask is equal to or less than the distance along the Z-direction to the nearest end of depth of field (DOF) for the imaging device from the near side of the mask,

the second alignment process including the movement of at least one of the substrate and the mask in the direction of reducing the calculated distance, which movement takes place concurrently with or subsequently to a relative approach at a second predetermined speed along the Z-direction between the substrate and the mask, the second predetermined speed being slower than the first predetermined speed.

As described, concurrently with a relative approach between the substrate and the mask, the distance between the X-Y position of a substrate-mark and the X-Y position of the associated mask-mark is calculated and at least one of the substrate and the mark is moved in a direction of reducing the calculated distance. Thus, this configuration may reduce the time required from the commencement of the alignment to the contact of the substrate and mask with each other.

### Technical Effects of the Invention

As described, the present invention can provide an alignment device intended to reduce the time required from the commencement of the alignment to the contact of the substrate and mask with each other.

### BRIEF DESCRIPTION OF THE DRAWINGS

FIG. 1 is a schematic perspective view of an alignment device according to an embodiment of the present invention.

FIG. 2A and FIG. 2B illustrates fields of view of a camera of the system according to the embodiment of the present invention, in which FIG. 2A is a schematic view of a field of view of the camera in a calibration step in which a substrate-mark is moved into the field of view but not aligned with a mask-mark, and FIG. 2B is a schematic view of the camera in the next calibration step in which the substrate-mark and the associated mask-mark are aligned.

FIG. 3 is a plot of approaching speed of the substrate toward the mask as well as a plot of alignment error of the marks obtained by the system according to the embodiment of the present invention.

FIG. 4 is a flowchart of the alignment processing according to an embodiment of the present invention.

FIG. 5A, FIG. 5B, and FIG. 5C illustrate an example of changes in position of the substrate and the mask as well as changes in position of alignment marks, in which FIG. 5A illustrates a substrate approaching but before the nearest end front end of depth of field, FIG. 5B illustrates the substrate reaching the nearest end of depth of field, and FIG. 5C illustrates the substrate entering depth of field beyond the nearest end of the depth of field.

FIG. 6 is a flowchart of the alignment processing according to the first one of other aspects of the embodiment of the present invention.

FIG. 7 is a flowchart of the alignment processing according to the second one of other aspects of the embodiment of the present invention.

### DETAILED DESCRIPTION OF THE INVENTION

Referring to the accompanying drawings, an implementing the present invention will be described in detail as follows.

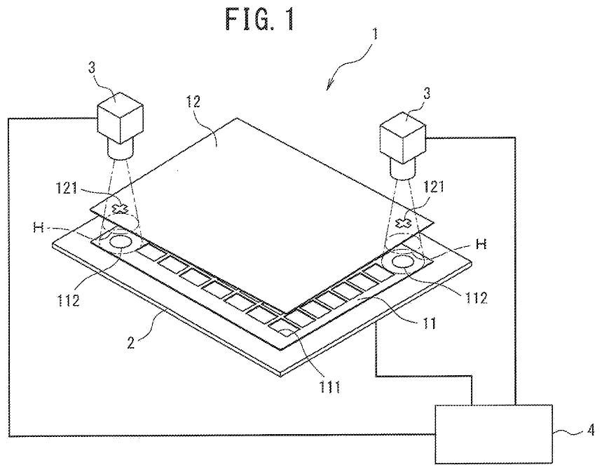

In FIG. 1, a film forming apparatus 1 is installed with an alignment device according to an embodiment of the present invention. Functional components of the film forming apparatus 1 include mounts such as a mount or holder 2, imaging units such as cameras 3, and a control unit 4.

The mount 2 is used to mount and fix a mask 11, which is used to form a thin-film with a predetermined pattern on a substrate 12, on its mounting surface. The mount 2 holds and keeps the mask 11 parallel to an X-Y plane (such as a horizontal plane) with one X-direction and one Y-direction as well as one Z-direction which runs orthogonally thereto.

The mask 11 has openings 111 in the predetermined pattern with which the thin-film is to be formed on the substrate 12. The mask 11 has mask-marks 112 or alignment markings which are used to measure the position of the mask 11. Each of the mask-marks 112 is in the form of a hole in the mask 11. The configuration of the mask-mark 112 is not limited to a hole, and it may be, for example, a concave, a convex, or any two-dimensional display. The openings 111 of the mask 11 are configured and arranged in shape and number depending on a pattern of the thin-film to be formed on the substrate 12, so are not limited to the illustrated shape and number of the present embodiment.

A second mount or holder, not shown, holds and keeps the substrate 12 parallel to the mask 11 that is kept parallel to the X-Y plane. The substrate 12 has substrate-marks 121 or alignment markings which are used to measure the position of the substrate 12. In the present embodiment, the substrate 12 is in the form of a glass substrate, and has the substrate-marks 121 located at areas which the thin film to be formed on the substrate 12 will not cover. Since the thin film is not formed in the vicinity of each of the substrate-marks 121, one can see through the vicinity of the substrate-mark 121 to identify the associated one of the mask-marks 112. Each of the substrate-marks 121 is formed of, for example, a thin film of opaque metal such as chromium.

In the present embodiment, at least two mask-marks 112 are located on the mask 11, while at least two substrate-marks 121 are located on the substrate 12. The places, where the mask-marks 112 and the substrate-marks 121 should be, are not limited to those of the present embodiment. The mask-marks 112 and the substrate-masks 121 are formed and located so that, upon making contact of the substrate 12 with the mask 11, each of the substrate-masks 121 may be aligned to the associated one of the mask-marks 112 with their centers matched when the openings 111 of the mask 11 are placed exactly where the openings 111 should be. This requirement, however, may be eliminated if the positions of the substrate 12 and the mask 11 can be detected and if, in the process of making the contact, the openings 111 of the mask 11 can be placed exactly where the openings 111 should be.

The second mount or holder can adjust the position and tilt angle of the substrate 12. The control unit 4 may instruct these actions. The holder can move the substrate 12 along the Z-direction. The control unit 4 may instruct this action.

The cameras 3 are used to measure the position of the substrate 12 and the position of the mask 11. The cameras 3 are configured and arranged to take images of the substrate 12 and the mask 11 from points separated, in a direction along the Z-direction, from the substrate 12 and the mask 11. Each of the cameras 3 is adjusted to take the image including a selected one of the substrate-marks 121 and the associated one of the mask-marks 112 at the same time. For measurement of the positions of the substrate 12 and the mask 11, the cameras 3 may include cameras, each being adjusted to take the image of a selected one of the substrate-marks 121, and include cameras, each being adjusted to take the image of a selected one of the mask-marks 112.

Each of the cameras 3 is adjusted to focus on the near side of the mask 11. The nearest end of depth of field (DOF) for the camera 3 is indicated at “H” in FIG. 1. The distance along the Z-direction to the nearest end “H” of DOF from the near side of the mask 11 is herein called “the distance to the nearest end “H” of DOF”. The distance to the nearest end “H” of DOF may be calculated or measured beforehand and stored in a memory of the control unit 4.

The control unit 4 controls the camera 3 and the second mount (or holder) which the substrate 12 is loaded to. The control unit 4 calculates the distance between the X-Y position of a substrate-mark 121 and the X-Y position of the associated mask-mark 112 using the data obtained from the image taken by the camera 3 focused on this mask-mark 112. Controlling a movement of the substrate 12 in a direction of reducing the calculated distance, the control unit 4 adjusts the position of the substrate 12 so that the substrate 12 may overlay the top surface of the mask 11 to place the openings 111 of the mask 11 exactly where the openings 111 should be. Instead of adjusting the position of the substrate 12, the control unit 4 may adjust the position of the mask 11 with the substrate fixed, or may adjust both of the position of the substrate 12 and the position of the mask 11.

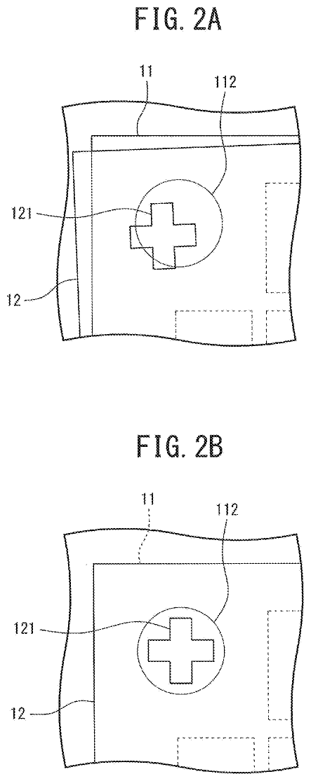

Concurrently with letting the substrate 12 approach the mask 11 along the Z-direction, the control unit 4 calculates the distance between the X-Y position of the substrate-mark 121 and the X-Y position of the mask-mark 112 using the image data shown in FIG. 2A; the control unit 4 determines a travel path along the X-Y plane in a direction of reducing the calculated distance and the control unit 4 makes the holder move the substrate 12 from the position of FIG. 2A to follow the determined travel path in order to reach an alignment position shown in FIG. 2B. In the alignment position shown in FIG. 2B, the substrate 12 is in close contact with the mask 11 with the substrate 12 overlaying the mask 11 and being lined up on top of the mask 11 along the Z-direction.

The control unit 4 corrects the displacement of the travel path depending on the distance along the Z-direction between the substrate 12 and the mask 11. For quantitative analysis of a measured value of the distance along the Z-direction between the substrate 12 and the mask 11, the control unit 4 may store retrievable varying values of a parameter with distinct groups which the distance is divided into. The control unit 4 may calculate a correction value using a mathematical formula involving a parameter that is a function of the distance along the Z-direction between substrate 12 and the mask 11.

The control unit 4 commences the execution of a first or less-precise alignment process following determination that the distance, along the Z-direction, between the substrate 12 and the mask 11 is greater than the distance, along the Z-direction, to the nearest end “H” of depth of field (DOF) from the near side of the mask 11. In the less-precise alignment process, an approach along the Z-direction from the substrate 12 to the mask 11 takes place at a predetermined high speed.

The substrate-mark 121 is out of the DOF for the camera 3 if the distance along the Z-direction between the substrate 12 and the mask 11 is greater than the distance to the nearest end “H” of the DOF from the mask 11. Thus, the substrate-mark 121 is imaged blurred and/or uncentered. In this case, the execution of the less-precise alignment process may be commenced if the X-Y position of the substrate-mark 121 is identified, with image processing, to enable calculation of the distance from the X-Y position of the substrate-mark 121 to the X-Y position of the associated mask-mark 112.

The control unit 4 commences the execution of a second or precise alignment process following determination that the distance along the Z-direction between the substrate 12 and the mask 11 is equal to or less than the distance along the Z-direction to the nearest end “H” of depth of field (DOF) from the near side of the mask 11. In the precise alignment process, an approach along the Z-direction from the substrate 12 to the mask 11 takes place at a slow-speed slower than the predetermined high-speed that is used in the less-precise alignment process.

The substrate-mark 121 is in the DOF for the camera 3 if the distance along the Z-direction between the substrate 12 and the mask 11 is equal to or less than the distance to the nearest end “H” of the DOF from the mask 11. Thus, the substrate-mark 121 are in focus, making it possible to execute the precise alignment process.

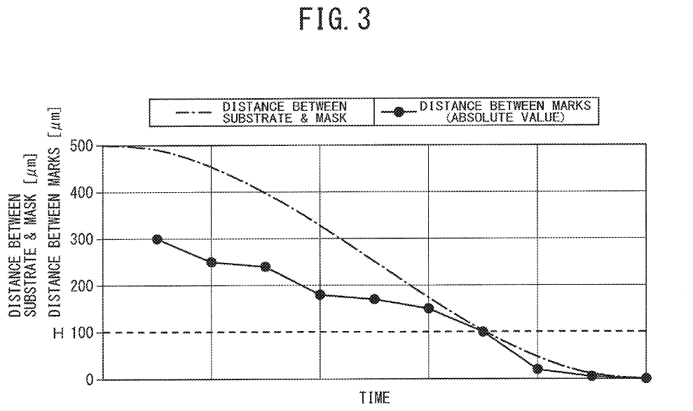

FIG. 3 depicts the less-precise alignment process and the precise alignment process according to the present embodiment. If the distance along the Z-direction between the substrate 12 and the mask 11 is greater than the distance along the Z-direction to the nearest end “H” of depth of field (DOF) from the near side of the mask 11, the substrate 12 is moved for a relative approach along the Z-direction between the substrate 12 and the mask 11 at a predetermined speed. Concurrently with such relative approach, the substrate 12 is moved in a direction of reducing a distance between the X-Y position of a substrate-mark 121 and the X-Y position of the associated mask-mark 112.

Subsequently, if the distance along the Z-direction between the substrate 12 and the mask 11 becomes equal to or less than the distance along the Z-direction to the nearest end “H” of depth of field (DOF) from the near side of the mask 11, the speed at which the relative approach takes place is reduced. Concurrently with the relative approach at the reduced speed, the distance between the X-Y position of the substrate-mark 121 and the X-Y position of the associated mask-mark 112 is calculated precisely. The substrate 12 is moved in a direction of reducing the distance between the X-Y position of the substrate-mark 121 and the X-Y position of the associated mask-mark 112 to complete the exact alignment of the substrate mark 121 to the associated mask-mark 112 immediately before making close contact between the substrate 12 and the mask 11.

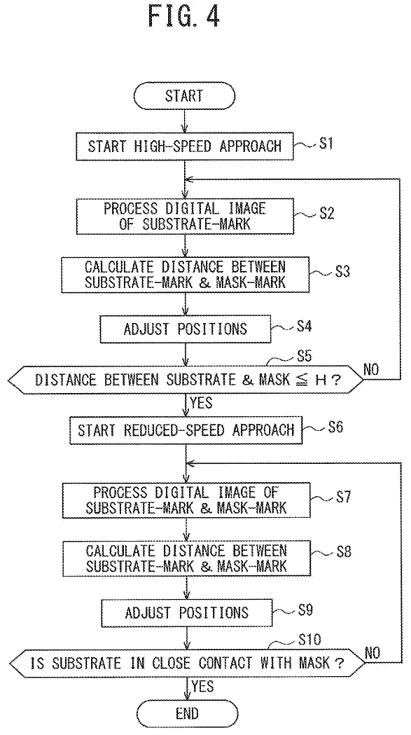

Referring to FIG. 4, the alignment processing in the system, which the present embodiment pertains to, configured as described above is described. The first step of the alignment processing, which is described below, is commenced in response to an input of an operator start command. The mask 11 has to be loaded to and fixed to the mount 2, the substrate 12 has to be loaded to and fixed to the second mount or holder. The mount 2 and the holder are calibrated so that a substrate-mark 121 and the associated mask-mark 112 should be in the field of view of one of the cameras 3 before the commencement of the alignment processing.

In step S1, the control unit 4 commences instructing a high-speed approach of the holder to the mount 2 in which the control unit 4 makes the holder keep the approach along the Z-direction taking place at a predetermined high speed. The control unit 4 continues to execute step S2 after step S1.

In step S2, the control unit 4 processes digital image of the substrate-mark 121 taken by the camera 3, which is adjusted to focus on the associated mask-mark 112, to determine the X-Y position of the substrate-mark 121. The control unit 4 continues to execute step S3 after step S2.

In step S3, the control unit 4 calculates the distance between the X-Y position of the substrate-mark 121 and the X-Y position, which may be determined beforehand, of the associated mask-mark 112. The control unit 4 continues to execute step S4 after step S3.

In step S4, the control unit 4 determines a new position, which the substrate 12 should move from the current position to, in a movement of the substrate 12 in a direction of reducing the calculated distance and processes the adjustment of the position of the substrate 12 to the new position. The control unit 4 continues to execute step S5 after step S4.

In step S5, the control unit 4 determines whether or not the distance along the Z-direction between the substrate 12 and the mask 11 is equal to or less than the distance along the Z-direction to the nearest end “H” of the DOF from the near side of the mask 11.

If the distance along the Z-direction between the substrate 12 and the mask 11 is greater than the distance along the Z-direction to the nearest end “H” of the DOF from the near side of the mask 11 (i.e., the terminal condition in step S5 is false), the control unit 4 enters the loop and continues to execute steps S2, S3 and S4 of the body of the loop and to reevaluate the condition in step S5. If the distance along the Z-direction between the substrate 12 and the mask 11 is equal to or less than the distance along the Z-direction to the nearest end “H” of the DOF from the near side of the mask 11 (i.e., the terminal condition in step S5 is true), the control unit 4 continues to execute step S6.

In step S6, the control unit 4 ceases instructing the high-speed approach of the holder to the mount 2 and commences instructing a reduced-speed approach of the holder to the mount 2 in which the control unit 4 makes the holder keep the approach along the Z-direction taking place at a speed slower than the high speed at which the high-speed approach takes place. This reduced-speed approach will continue till determination in step S10, later described, whether the substrate 12 contacts with the mask 11.

In step S7, the control unit 4 processes the digital image of the substrate mark 121 and the mask mark 112 taken by the camera 3, which is adjusted to focus on the mask-mark 112 to determine the X-Y position of the substrate-mark 121 and the X-Y position of the associated mask-mark 112. The control unit 4 continues to execute the process of step S8 after step S7.

In step S8, the control unit 4 calculates the distance between the X-Y position of the substrate-mark 121 and the X-Y position of the associated mask-mark 112. The control unit 4 continues to execute step S9 after step S8.

In step S9, the control unit 4 determines the displacement, by which the substrate 12 should move from the current position to a new position, in a movement of the substrate 12 in a direction of reducing the calculated distance and processes the adjustment of the substrate 12 to the new X-Y position. The control unit 4 continues to execute step S10 after step S9.

In step S10, the control unit 4 determines whether or not the substrate 12 contacts with the mask 11.

If the substrate 12 is not in close contact with the mask 11, the control unit 4 enters the loop and continues to execute steps S7, S8 and S9 of the body of the loop and to reevaluate the condition in step S10. If the substrate 12 is in close contact with the mask 11, the control unit 4 exists.

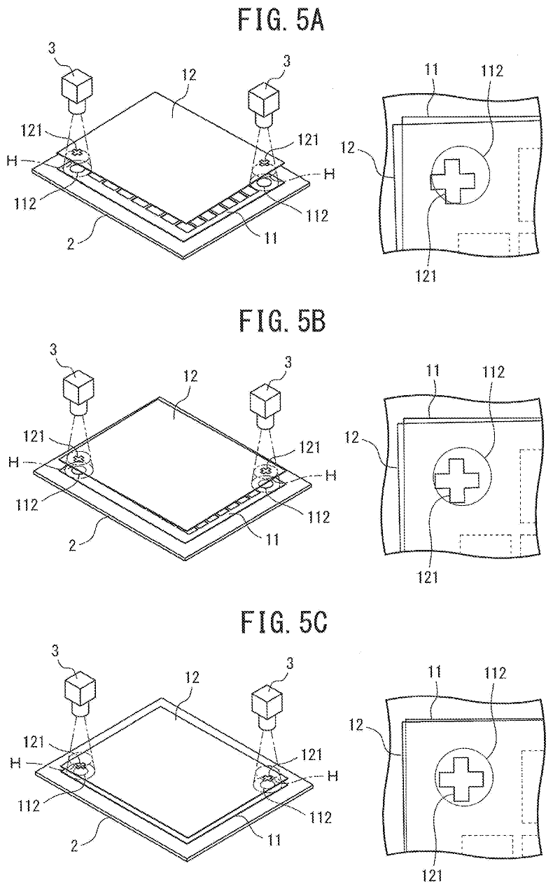

Referring to FIG. 5A, FIG. 5B and FIG. 5C the movements kept by the above-described alignment processing are described. With the substrate 12 being separated from the mask 11 in a direction along the Z-direction more than the nearest end “H” of DOF for the camera 3 is separated from the mask 11 as depicted in FIG. 5A, the less-precise alignment process is executed. The less-precise alignment process includes a movement of the substrate 12 in a direction of reducing the distance between the X-Y position of a substrate-mark 121 and the X-Y position of the associated mask-mark 112, which movement takes place concurrently with a relative approach taking place at a predetermined high speed along the Z-direction between the substrate 12 and the mask 11. Repeating the execution of this less-precise process keeps the X-Y position of the substrate-mark 121 moving toward the X-Y position of the associated mask-mark 112, keeping the position of the substrate 12 moving toward the position of the mask 11.

Subsequently, as depicted in FIG. 5B, after and upon an approach of the substrate 12 to the nearest end “H” of DOF, the execution of the precise alignment process is commenced. During the execution of the precise alignment system, the distance between the X-Y position of the substrate-mark 121 and the X-Y position of the associated mask-mark 112 is precisely calculated. The precise alignment system includes the movement of the substrate 12 in a direction of reducing the precisely calculated distance, which movement takes place concurrently with a relative approach taking place at a speed slower than the predetermined speed along the Z-direction between the substrate 12 and the mask 11. Repeating the execution of this precise alignment process keeps the X-Y position of the substrate-mark 121 moving toward the X-Y position of the associated mask-mark 112, keeping the position of the substrate 12 moving toward the position of the mask 11.

As depicted in FIG. 5C, immediately before the substrate 12 contacts with the mask 11, the substrate-mark 121 is about to align to the associated mask-mark 112 with high accuracy. Subsequently, when the substrate 12 contacts with the mask 11, the substrate mark 121 aligns to the associated mask-mark 112 with their centers matching to make the substrate 12 overlay the mask 11.

As described, in the present embodiment, concurrently with a high-speed approach of the substrate 12 along the Z-direction to the mask 11, the position of the substrate 12 and the position of the mask 11 are adjusted in a direction of reducing the distance between the X-Y position of the substrate-mark 121 and the X-Y position of the associated mask-mark 112 if the distance along the Z-direction between the substrate 12 and the mask 11 is greater than the distance along the Z-direction to the nearest end “H” of depth of field (DOF) from the near side of the mask 11. Concurrently with a reduced-speed approach slower than the high-sped approach of the substrate 12 along the Z-direction to the mask 11, the position of the substrate 12 and the position of the mask 11 are adjusted in the direction of reducing the distance between the X-Y position of the substrate-mark 121 and the X-Y position of the mask-mark 112 if the distance along the Z-direction between the substrate 12 and the mask 11 is equal to or less than the distance along the Z-direction to the nearest end of depth of field (DOF) from the near side of the mask 11.

As described, concurrently with an approach of the substrate 12 to the mask 11, the distance between the X-Y position of the substrate-mark 121 and the X-Y position of the associated mask-mark 112 is calculated and the position of the substrate 12 and the position of the mask 11 are adjusted. This reduces the time required from the commencement of the alignment to the contact of the substrate 12 with the mask 11.

Moreover, the less precise alignment is executed if the distance along the Z-direction between the substrate and the mask is greater than the distance along the Z-direction to the nearest end of depth of field (DOF) from the near side of the mask, while the precise alignment process is executed if the distance along the Z-direction between the substrate and the mask is equal to or less than the distance along the Z-direction to the nearest end of depth of field (DOF) from the near side of the mask. This enables high-precision adjustment of the position of the substrate 12 and the position of the mask 11.

Moreover, the alignment is completed immediately before the substrate 12 contacts with the mask 11 and only one contact with the mask 11 suffices, effectively preventing damages to the substrate 12.

Furthermore, the adjustment of the position of the substrate 12 and the position of the mask 11 is precise because of the position correction with a correction value dependent on the distance along the Z-direction between the substrate 12 and the mask 11.

In accordance with the first one of other aspects of the present embodiment, a control unit 4 depicted in FIG. 1 makes a substrate 12 approach a mask 11 till the nearest end, as indicated at “H” in FIG. 2A and FIG. 2B, of field of depth (DOF) before executing a precise alignment process. Using the distance to the nearest end of the DOF from the near side of the mask 11 stored in its memory, the control unit 4 makes the substrate 12 approach the mask 11 till the nearest end “H” of the DOF.

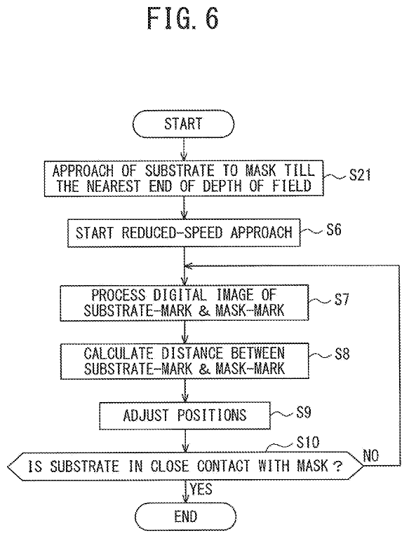

Referring now to FIG. 6, the alignment processes, to which the first one of other aspects of the alignment device described above pertains, will be described. The first step of the alignment processes described below is commenced in response to an operator command to start the alignment.

In step S21, a control unit 4 controls a holder, to which a substrate 12 is loaded, to make the substrate approach a mask 11 till the nearest end “H” of depth of field (DOF). The control unit 4 continues to execute step S6 after step S21.

The control unit 4 executes steps S6, S7, S8, S9 and step S10 in the same way as the control unit executes steps S6, S7, S8, S9 and step S10 in FIG. 4. The control unit 4 commences the execution of a reduced-speed approach of the holder toward a mount 2, to which a mask 11 is loaded, processes the image of a substrate-mark 121 and that of the associated mask-mark 112, calculates the distance between the X-Y position of the substrate-mark 121 and the X-Y position of the mask-mark 112, adjusts the position of the substrate 12 in a direction of reducing the calculated distance, and determines whether or not the substrate 12 is in close contact with the mask 11. If the substrate 12 is not in close contact with the mask 11, the control unit 4 enters the loop and continues to execute steps S7, S8 and S9 of the body of the loop and to reevaluate the condition in step S10. If the substrate 12 is in close contact with the mask 11, the control unit 4 exists.

As described, in the first one of other aspects of the present embodiment, a so-called high-speed less-precise alignment is eliminated, further reducing the time required from the commencement of the alignment to the contact of the substrate 12 with the mask 11.

In accordance with the second one of other aspects of the present embodiment, a control unit 4 depicted in FIG. 1 is configured to work as a stepping controller for controlling an approach of a holder, which a substrate 12 is loaded to, to a mount 2, which a mask 11 is loaded to. The control unit 4 executes a less-precise alignment process including multiple number of discrete steps, each causing a transitional motion of the substrate 12 over a predetermined increased length at increased speed. On the other hand, the control unit 4 executes a precise alignment process including multiple number of discrete steps, each causing a transitional motion of the substrate 12 over a predetermined reduced length at a reduced speed.

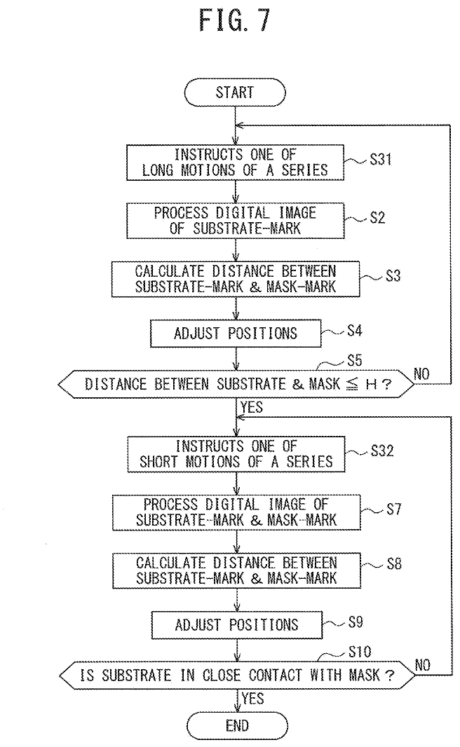

Referring now to FIG. 7, the alignment processing, to which the second one of other aspects of the alignment device described above pertains, will be described. The first step of the alignment processing described below is commenced in response to an input of an operator command to start the alignment.

In step S31, the control unit 4 instructs a first series of motions of the holder, each motion having a predetermined duration. In detail, the control unit 4 instructs one of the motions of the first series to provide one segment of the approach of the substrate 12 to the mask 11 in the less-precise alignment process. The control unit 4 executes step S2 after step S31.

The control unit 4 executes steps S2, S3, S4 and step S5 in the same way as the control unit executes steps S2, S3, S4 and step S5 in FIG. 4. In step S2, the control unit 4 processes the digital image of a substrate-mark 121 to determine a X-Y position; in step S3, the control unit 4 calculates the distance between the X-Y position of the substrate-mark 121 and the X-Y position of the associated mask-mark 112; in step S4, the control unit 4 determines a new X-Y position, which the substrate 12 should move from the current X-Y position to, in a movement of the substrate 12 in a direction of reducing the calculated distance and processes the adjustment of the position of the substrate 12 to the new X-Y position, and in step S5, the control unit 4 determines whether or not the distance along the Z-direction between the substrate 12 and the mask 11 is equal to or less than the distance along the Z-direction to the nearest end “H” of the DOF from the near side of the mask 11. If the distance along the Z-direction between the substrate 12 and the mask 11 is not equal to or not less than the distance along the Z-direction to the nearest end “H” of the DOF from the near side of the mask 11, the control unit 4 enters the loop and continues to execute steps S31, S2, S3 and S4 of the body of the loop and to reevaluate the condition in step S5. If the distance along the Z-direction between the substrate 12 and the mask 11 is equal to or less than the distance along the Z-direction to the nearest end “H” of the DOF from the near side of the mask 11, the control unit 4 continues to execute step S32.

In step S32, the control unit 4 instructs a second series of motions of the approach of the holder, each motion having a predetermined duration shorter than the first-mentioned duration and a rate that is slower than the rate each of the motions of the first series has. In detail, the control unit 4 instructs one of the motions of the second series to provide one segment of the approach of the substrate 12 to the mask 11 in the precise alignment process. The control unit 4 continues to execute step S7 after step S32.

The control unit 4 executes steps S6, S7, S8, S9 and step S10 in the same way as the control unit executes steps S6, S7, S8, S9 and step S10 in FIG. 4. The control unit 4 commences the execution of a reduced-speed approach of the holder toward a mount 2, to which a mask 11 is loaded, processes the image of a substrate-mark 121 and that of the associated mask-mark 112, calculates the distance between the X-Y position of the substrate-mark 121 and the X-Y position of the mask-mark 112, adjusts the position of the substrate 12 in a direction of reducing the calculated distance, and determines whether or not the substrate 12 is in close contact with the mask 11. If the substrate 12 is not in close contact with the mask 11, the control unit 4 enters the loop and continues to execute steps S32, S7, S8 and S9 of the body of the loop and to reevaluate the condition in step S10. If the substrate 12 is in close contact with the mask 11, the control unit 4 exists.

As described above, in the second one of other aspects of the present embodiment, the less-precise alignment process has a first series of motions of the holder for the substrate 12, each motion having a long duration and a high rate, while the precise alignment process has a second series of motions of the holder for the substrate 12, each motion having a relatively short duration and a relatively low rate.

As described, concurrently with an approach of the substrate 12 to the mask 11, the difference between the X-Y position of the substrate-mark 121 and the X-Y position of the associated mask-mark 112 and the position of the substrate 12 is adjusted. This reduces the time required from the commencement of the alignment to the contact of the substrate 12 with the mask 11

Although the embodiments of the present invention have been disclosed, it is clear that a person skill in the art can make changes without departing from the scope of the present invention. All such modifications and equivalents are intended to be included in the following claims.

### DESCRIPTION OF THE NUMERALS

1 thin film deposition equipment
2 mount (or holder)
3 camera (imaging device)
4 control unit
11 mask
12 substrate
112 mask-mark
121 substrate-mark

1. An alignment device, comprising:
an imaging device adjusted to focus on the near side of a mask for taking an image including a substrate-mark on a substrate and the associated mask-mark on the mask; and
a control unit configured to calculate the distance between the X-Y position of the substrate-mark and the X-Y position of the associated mask-mark using the data obtained from the image taken by the imaging device,
the control unit executing a first alignment process following the determination that the distance along the Z-direction between the substrate and the mask is greater than the distance along the Z-direction to the nearest end of depth of field (DOF) for the imaging device from the near side of the mask,
the first alignment process including a movement of at least one of the substrate and the mask in a direction of reducing the calculated distance, which movement takes place concurrently with a first relative approach taking place at a first predetermined speed along the Z-direction between the substrate and the mask, and
the control unit executing a second alignment process following the determination that the distance along the Z-direction between the substrate and the mask is equal to or less than the distance along the Z-direction to the nearest end of depth of field (DOF) for the imaging device from the near side of the mask,
the second alignment process including the movement of at least one of the substrate and the mask in the direction of reducing the calculated distance, which movement takes place concurrently with a second relative approach taking place at a second predetermined speed along the Z-direction between the substrate and the mask, the second predetermined speed being slower than the first predetermined speed.

2. The system as claimed in claim 1, wherein
following determination that the distance along the Z-direction between the substrate and the mask is greater than the distance along the Z-direction to the nearest end of depth of field (DOF) for the imaging device from the near side of the mask, the control unit instructs one of motions of a first series, each motion having a first predetermined duration, to provide a segment of the first relative approach in each cycle of repletion of the execution of the first alignment process, and
following determination that the distance along the Z-direction between the substrate and the mask is less than or equal to the distance along the Z-direction to the nearest end of depth of field (DOF) for the imaging device from the near side of the mask, the control unit instructs one of motions of a second series, each motion having a second predetermined duration, which is less than the first predetermined duration, to provide a segment of the second relative approach in each cycle of repetition of the execution of the second alignment process.

3. An alignment device, comprising:
an imaging device adjusted to focus on the near side of a mask for taking an image including a substrate-mark on a substrate and the associated mask mark on the mask; and
a control unit configured to calculate the distance between the X-Y position of the substrate-mark and the X-Y position of the associated mask-mark using the data obtained from the image taken by the imaging device,
the control unit controls a first relative approach along the Z-direction between the substrate and the mask until the distance along the Z-direction between the substrate and the mask is equal to the distance along the Z-direction to the nearest end of depth of field (DOF) for the imaging device from the near side of the mask, and subsequently executes an alignment process including a movement of at least one of the substrate and the mask in a direction of reducing the calculated distance, which movement takes place concurrently with a second relative approach taking place at a predetermined speed along the Z-direction between the substrate and the mask.

4. The system as claimed in claim 1, wherein
the control unit executes the position correction for the movement of at least one of the substrate and the mask in a direction of reducing the calculated distance, using a correction value dependent on the distance along the Z-direction between the substrate and the mask.

5. A method for alignment and contact-making of a substrate with a mask, using an imaging device adjusted to focus on the near side of a mask for taking an image including a substrate-mark on a substrate and the associated mask-mark on the mask, and a control unit configured to calculate the distance between the X-Y position of the substrate-mark and the X-Y position of the associated mask-mark using the data obtained from the image taken by the imaging device, the method comprising:
executing a first alignment process following determination that the distance along the Z-direction between the substrate and the mask is greater than the distance along the Z-direction to the nearest end of depth of field (DOF) for the imaging device from the near side of the mask,
the first alignment process including a movement of at least one of the substrate and the mask in a direction of reducing the calculated distance, which movement takes place concurrently with a relative approach taking place at a predetermined speed along the Z-direction between the substrate and the mask, and
executing a second alignment process following determination that the distance along the Z-direction between the substrate and the mask is equal to or less than the distance along the Z-direction to the nearest end of depth of field (DOF) for the imaging device from the near side of the mask,
the second alignment process including the movement of at least one of the substrate and the mask in the direction of reducing the calculated distance, which movement takes place concurrently with or subsequently to a relative approach at a second predetermined speed along the Z-direction between the substrate and the mask, the second predetermined speed being slower than the first predetermined speed.

6. The system as claimed in claim 2, wherein
the control unit executes the position correction for the movement of at least one of the substrate and the mask in a direction of reducing the calculated distance, using a correction value dependent on the distance along the Z-direction between the substrate and the mask.

7. The system as claimed in claim 3, wherein
the control unit executes the position correction for the movement of at least one of the substrate and the mask in a direction of reducing the calculated distance, using a correction value dependent on the distance along the Z-direction between the substrate and the mask.
